(19) United States
(12) Patent Application Publication
(10) Pub. No.: US 2026/0023891 A1
(43) Pub. Date: Jan. 22, 2026

(54) METHOD AND DEVICE FOR PREDICTING PASSENGER FLOW PATTERNS DURING SERVICE DISRUPTIONS IN A METRO NETWORK OF A MULTI-MODAL TRANSPORTATION NETWORK

(71) Applicants: The Hong Kong University of Science and Technology, Hong Kong (CN); MTR Corporation Limited, Hong Kong (CN)

(72) Inventors: Hong Kam LO, Hong Kong (CN); Enoch LEE, Hong Kong (CN); Kejun DU, Hong Kong (CN); May TSO, Hong Kong (CN)

(21) Appl. No.: 19/272,190

(22) Filed: Jul. 17, 2025

Related U.S. Application Data
(60) Provisional application No. 63/672,259, filed on Jul. 17, 2024.

(51) Int. Cl. G06F 30/18; G06F 30/27; G06Q 50/40

(52) U.S. Cl. CPC G06F 30/18; G06F 30/27; G06Q 50/40

(57) ABSTRACT

A computer-implemented method (100) for predicting passenger flow patterns during service disruptions in a metro network of a multi-modal transportation network. The method comprises: providing (105) first information associated with the metro network; providing (110) second information associated with alternative modes of transportation to the metro network in the multi-modal transportation network; providing (115) third information associated with the topology of a portion in the metro network associated with a service disruption; providing (120) fourth information associated with estimated diverted origin-destination-station (ODS) demand patterns for the service disruption; providing (125) fifth information associated with predicted irregular route choices of passengers in the multi-modal transportation network during service disruptions; and predicting (130) passenger flow patterns associated with the service disruption, through computationally simulating, based collectively on the first information, the second information, the third information, the fourth information and the fifth information.

### CROSS REFERENCE TO RELATED APPLICATIONS

The present application claims priority to Provisional Application No. 63/672,259 filed in the U.S. Patent and Trademark Office on Jul. 17, 2024, the entire contents of which are incorporated herein by reference.

### TECHNICAL FIELD

The following relates generally to prediction of passenger flow patterns in near real-time, during rail service disruptions, and more specifically, it relates to a computer-implemented method and a related device for predicting passenger flow patterns during service disruptions in a metro network of a multi-modal transportation network.

### BACKGROUND

During metro rail service disruptions, passengers (at stations) may typically exhibit several different behaviors: some passengers may wait until the disruption ends; some passengers may reroute within the metro network; while other passengers may seek alternative transportation modes outside the metro network to continue their journey. So, the affected passengers diverge from their usual usage patterns, with the stations and trains loading being significantly different from a typical day, where there are good rail services.

By better understanding passenger behavior and hence metro system performance during service disruptions, metro rail operators may develop mitigation strategies for emergency response management, such as adjusting service operations for the trains, or deploying substitute buses to reduce the delays and improve passenger experiences.

For transportation system planning and modeling, Multi-Agent Transport Simulation Model (MATSim) is a commonly used open-source dynamic simulation model that simulates individual agents' travel choice decisions and their congestion interactions on the system performance. MATSim is based on activity-based modeling: it incorporates the behavioral richness of linking people's activity patterns, and is designed for large-scale scenarios, and performs integral microscopic simulation of resulting traffic flows and the congestion produced by those traffic flows. Since MATSim contains behavioral parameters for the agents, in addition to a variety of parameters, the agents' rerouting decisions across multiple transportation modes may be captured.

Nevertheless, MATSim is computationally expensive, since it considers detailed network information, including the road network attributes, dynamic signal timing, and public transport schedules and routes for all major modes. MATSim is also not calibrated to model passenger route choice behavior under service disruptions. MATSim requires long simulation times to perform a simulation, and multiple iterations of the simulation must be performed to obtain an equilibrium solution, further compounding the computation time. For example, in the case of Hong Kong as a locale, a complete run of a simulation in MATSim tends to require more than 20 days of computational time. As such, predictions cannot be produced in a timely manner to be practically useful.

Hence, metro system operators are unable to use MATSim to predict the outcomes of a service disruption in order to allocate management resources in a timely manner. Furthermore, the assumption of equilibrium passenger route choices may not be applicable, as during a service disruption, passengers generally do not have perfect information about alternative routes to make repeated choices to arrive at an equilibrium solution.

That is, in transportation engineering, there generally lacks a model to quickly predict the passenger flow patterns in near real-time, especially under disruptive operating conditions. Hence, there is a need for a solution that may address at least one of the problems of the prior art, and/or to provide a choice useful in the art.

### SUMMARY

The described techniques herein may relate to a computer-implemented method and a related device for predicting passenger flow patterns during service disruptions in a metro network of a multi-modal transportation network. A non-limiting object of the proposed methodology is to significantly improve metro rail operators' ability to manage rail service disruptions.

According to a 1^{st} aspect, there is disclosed a computer-implemented method for predicting passenger flow patterns during service disruptions in a metro network of a multi-modal transportation network, the method comprises: providing first information associated with the metro network, which include the topology of the metro network, service schedules of trains in the metro network, and information on fares for the trains; providing second information associated with alternative modes of transportation to the metro network in the multi-modal transportation network, which include information on fares for the alternative modes of transportation, and expected travel time for routes based on the alternative modes of transportation; providing third information associated with the topology of a portion in the metro network associated with a service disruption; providing fourth information associated with estimated diverted origin-destination-station (ODS) demand patterns for the service disruption; providing fifth information associated with predicted irregular route choices of passengers in the multi-modal transportation network during service disruptions; and predicting passenger flow patterns associated with the service disruption, through computationally simulating, based collectively on the first information, the second information, the third information, the fourth information and the fifth information.

Preferably, predicting the passenger flow patterns may include: outputting information on link flows along each metro line, and number of waiting passengers on the platforms arranged at the portion in the metro network associated with the service disruption.

Preferably, the topology of the portion in the metro network may indicate at least one station affected by said service disruption.

Preferably, providing the fourth information associated with the estimated diverted ODS demand patterns may include: configuring a graph neural network (GNN) to capture spatial and temporal information embedded in the metro network, wherein the GNN is further configured with information on the topology of the metro network; providing, to the GNN, the third information; providing, to the GNN, sixth information on origin-destination-station (ODS) pair passenger demand numbers associated with the service disruption; and estimating, by the GNN based on the third information and the sixth information, passenger diversion behaviour for each ODS pair, which collectively enable generation of the estimated diverted ODS demand patterns as the fourth information.

Preferably, the method may further comprise calibrating the number of ODS pair associated with the service disruption to match the estimated diverted ODS demand patterns.

Preferably, the information on the topology of the metro network may include information associated with costs of traveling between stations in the metro network and on links.

Preferably, the GNN may be pre-trained with historical ODS demand patterns that are based on smart card data associated with travelling in the metro network, and in the historical ODS demand patterns, regular passengers with habitual travel patterns may be identified as representative tracers to enable determination of passenger irregular route choices during service disruptions, based on the habitual travel patterns of said representative tracers.

Preferably, the smart card data associated with travelling in the metro network may include data associated with travelling in the metro network during service disruptions, and data associated with travelling in the metro network during disruption-free operation thereof.

Preferably, the first information may further include information on the types of trains operating in the metro network, and respective capacities of the trains.

Preferably, computationally simulating to predict the passenger flow patterns may be performed by an event-based metro system simulation model.

Preferably, the event-based metro system simulation model may be configured at least with information being: historical ODS demand patterns that are based on smart card data associated with travelling in the metro network, wherein the smart card data include data associated with travelling in the metro network during service disruptions, and data associated with travelling in the metro network during disruption-free operation thereof; and passenger load information of the trains during service disruptions, and during disruption-free operation of the metro network.

According to a 2^{nd} aspect, there is disclosed a computing device for predicting passenger flow patterns during service disruptions in a metro network of a multi-modal transportation network, comprising: one or more memories having executable code; and one or more processors coupled to the one or more memories, and configured to execute the code to cause the device to: provide first information associated with the metro network, which include the topology of the metro network, service schedules of trains in the metro network, and information on fares for the trains; provide second information associated with alternative modes of transportation to the metro network in the multi-modal transportation network, which include information on fares for the alternative modes of transportation, and expected travel time for routes based on the alternative modes of transportation; provide third information associated with the topology of a portion in the metro network associated with a service disruption; provide fourth information associated with estimated diverted origin-destination-station (ODS) demand patterns for the service disruption; provide fifth information associated with predicted irregular route choices of passengers in the multi-modal transportation network during service disruptions; and predict passenger flow patterns associated with the service disruption, through computationally simulating, based collectively on the first information, the second information, the third information, the fourth information and the fifth information.

According to a 3^{rd} aspect, there is disclosed a computing device for predicting passenger flow patterns during service disruptions in a metro network of a multi-modal transportation network, comprising: means for providing first information associated with the metro network, which include the topology of the metro network, service schedules of trains in the metro network, and information on fares for the trains; means for providing second information associated with alternative modes of transportation to the metro network in the multi-modal transportation network, which include information on fares for the alternative modes of transportation, and expected travel time for routes based on the alternative modes of transportation; means for providing third information associated with the topology of a portion in the metro network associated with a service disruption; means for providing fourth information associated with estimated diverted origin-destination-station (ODS) demand patterns for the service disruption; means for providing fifth information associated with predicted irregular route choices of passengers in the multi-modal transportation network during service disruptions; and means for predicting passenger flow patterns associated with the service disruption, through computationally simulating, based collectively on the first information, the second information, the third information, the fourth information and the fifth information.

According to a 4^{th} aspect, there is disclosed a non-transitory computer-readable medium comprising executable code, which when executed by a processor of a computing device, cause the device to perform the method of the 1^{st} aspect.

Additional benefits and advantages of the disclosed aspects may become apparent from the specification and drawings. The benefits and/or advantages may be individually obtained by the various aspects and features of the specification and drawings, which need not all be provided in order to obtain one or more of such benefits and/or advantages.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various aspects and to explain various principles and advantages in accordance with the present disclosure.

FIG. 1 is a flowchart depicting a computer-implemented method for predicting passenger flow patterns during service disruptions in a metro network of a multi-modal transportation network, in accordance with aspects of the present disclosure.

FIG. 2 is a schematic representation of the method of FIG. 1, in accordance with aspects of the present disclosure.

FIG. 3 is a schematic representation of a statistical model for generating estimated diverted origin-destination-station (ODS) demand patterns, in accordance with aspects of the present disclosure.

FIG. 4 is a flowchart depicting a method for identifying regular passengers with habitual travel patterns from smart card data associated with travelling in a metro network, in accordance with aspects of the present disclosure.

FIG. 5 is a schematic representation of an implementation of an event-based metro system simulation model used in the method of FIG. 1, in accordance with aspects of the present disclosure.

FIGS. 6 and 7 are block diagrams of devices for predicting passenger flow patterns during service disruptions in a metro network of a multi-modal transportation network, in accordance with aspects of the present disclosure.

FIG. 8 is a block diagram of a compute manager for predicting passenger flow patterns during service disruptions in a metro network of a multi-modal transportation network, in accordance with aspects of the present disclosure.

FIG. 9 is a schematic diagram of an exemplary computing device for performing the method of FIG. 1, in accordance with aspects of the present disclosure.

FIG. 10 is a schematic diagram of an exemplary computing device for performing the method of FIG. 1, in accordance with aspects of the present disclosure.

### DETAILED DESCRIPTION

Aspects of the present disclosure set out a method and a corresponding device for predicting passenger flow patterns during service disruptions in a metro network of a multi-modal transportation network.

It is to be appreciated that while the following description provides examples of method(s) and corresponding device(s) for predicting passenger flow patterns during service disruptions in a metro network of a multi-modal transportation network, they are not limiting on the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented, or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein.

It should be understood that any aspect of the disclosure disclosed herein may be embodied by one or more elements of a claim. The word “exemplary” is used herein to mean “serving as an example, instance, or illustration”. Any aspect described herein as “exemplary” is not necessarily to be construed as preferred or advantageous over other aspects.

Aspects according to the present disclosure will be described, by way of example only, with reference to the drawings. Like reference numerals and characters in the drawings refer to like elements or equivalents.

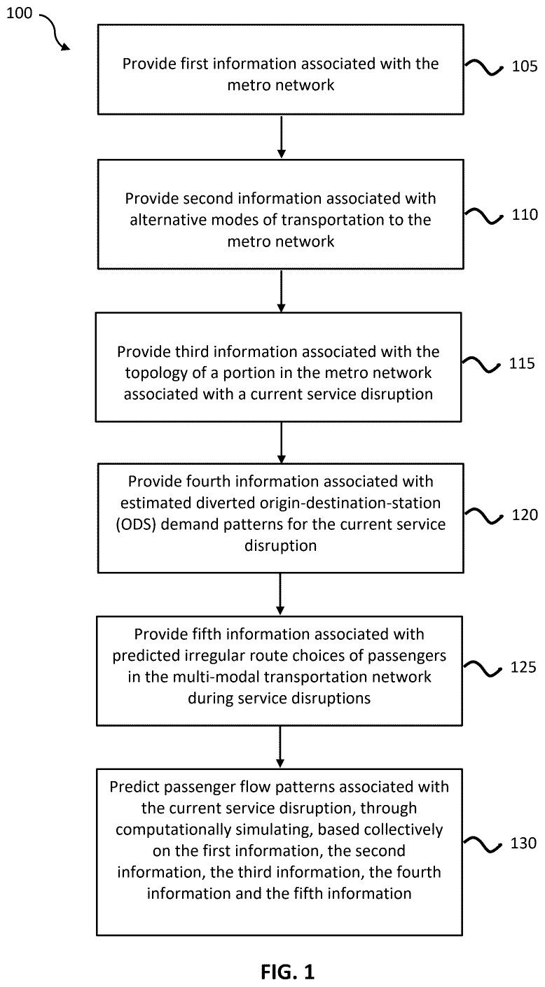

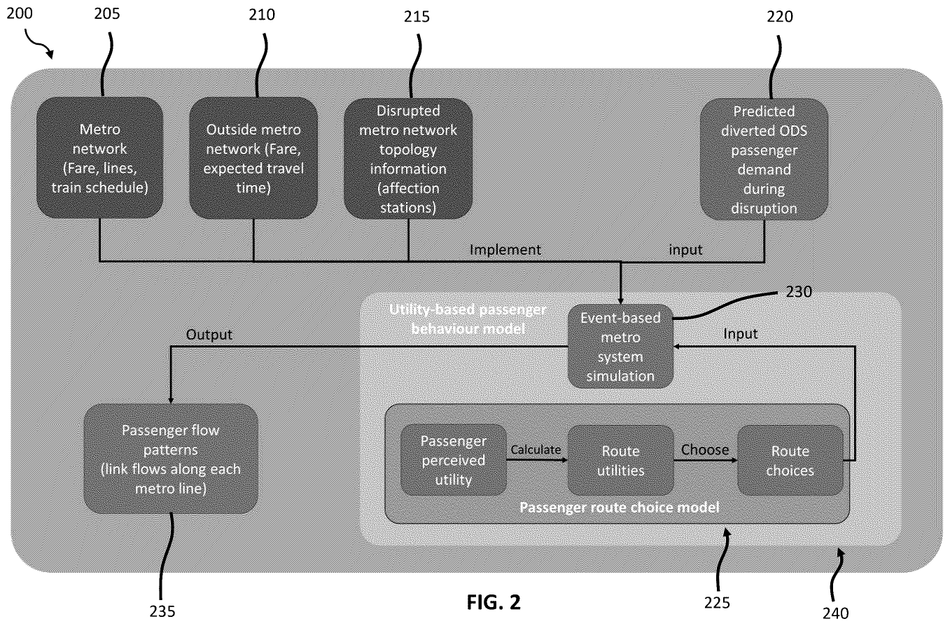

FIG. 1 is a flowchart illustrating a computer-implemented method 100 for predicting passenger flow patterns during service disruptions in a metro network of a multi-modal transportation network, in accordance with aspects of the present disclosure. Description of the method 100 is also made referring to FIG. 2, which depicts a schematic representation 200 of said method 100.

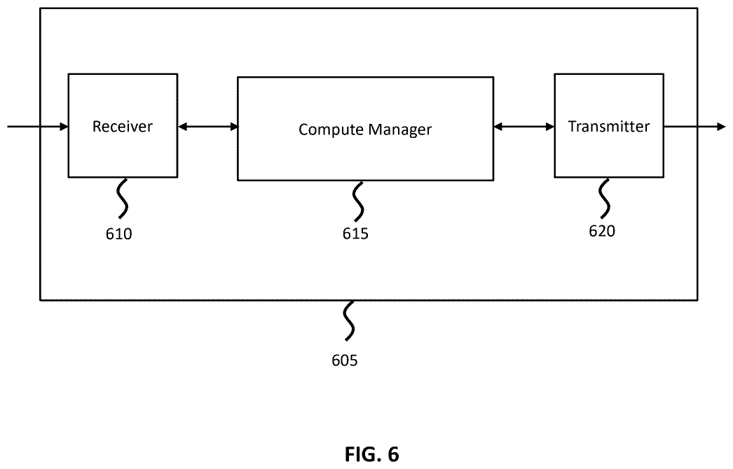

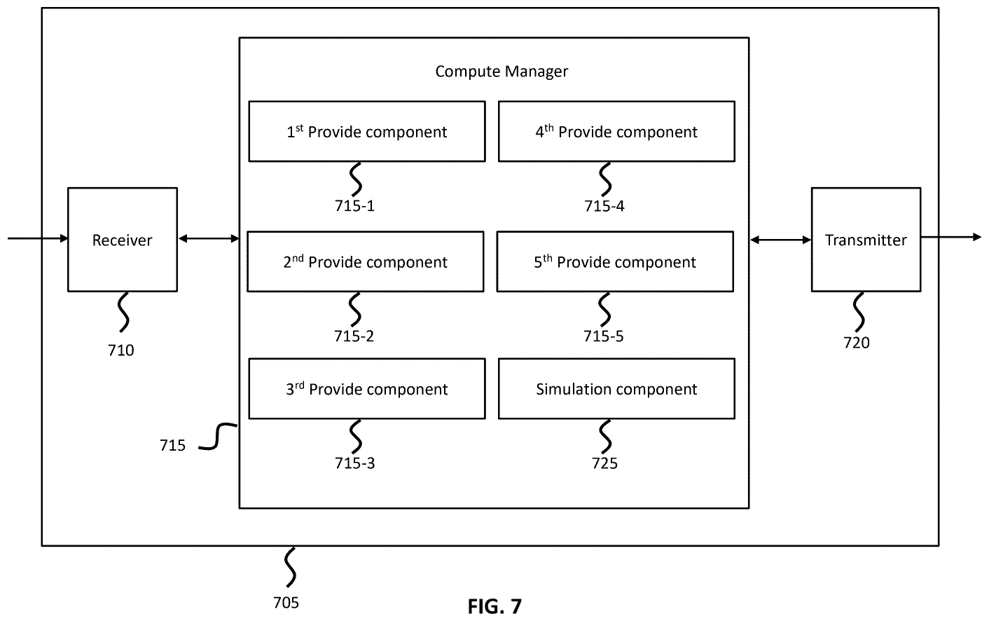

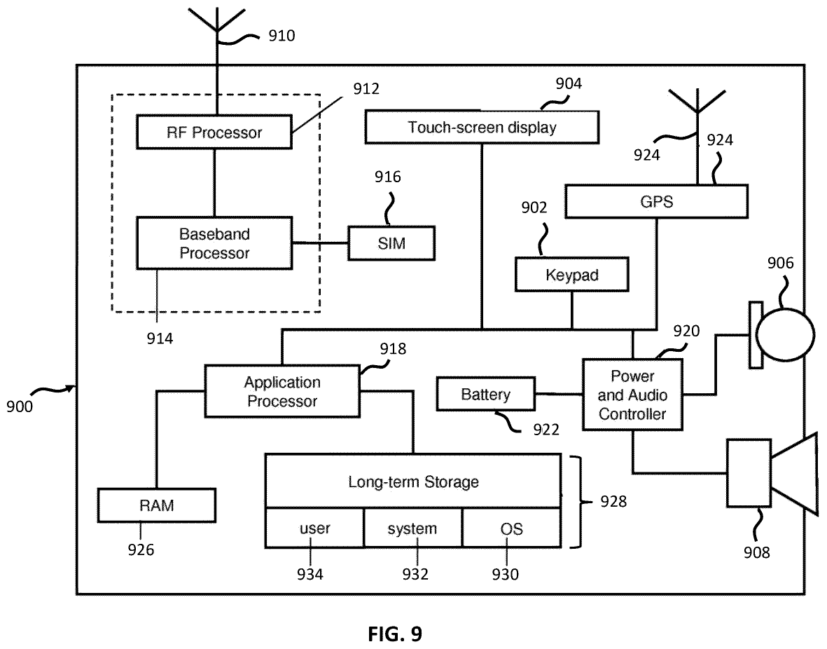

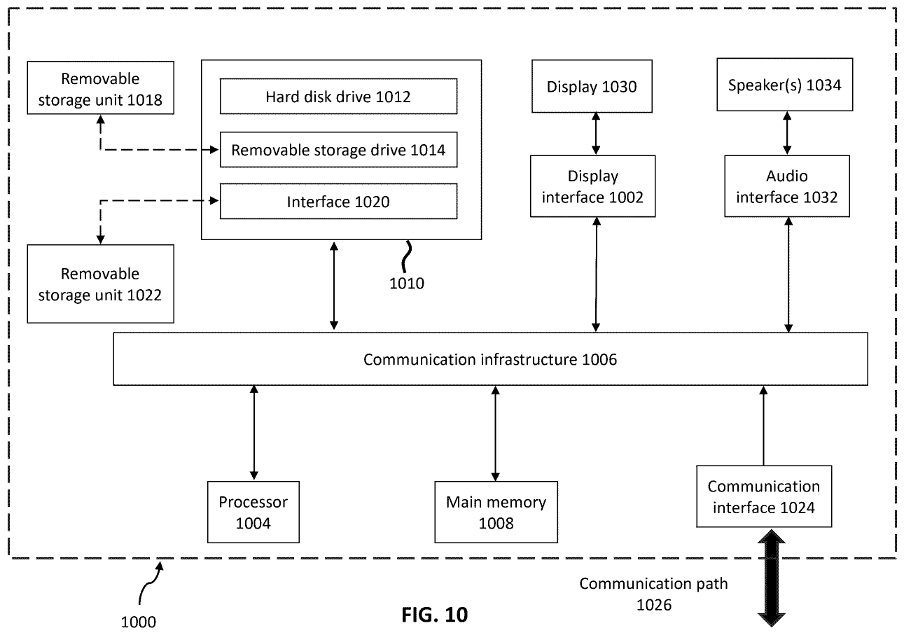

The operations of method 100 may be implemented by a computing device 900, 1000 (or its components), as depicted in FIGS. 9-10. For example, the operations of method 100 may be performed by a compute manager 615, 715 as described with reference to FIGS. 6-7, which may be installed and executed on the computing device 900, 1000 (or its components). In some examples, the computing device 900, 1000 (or its components) may execute a set of instructions to control the functional elements of the computing device 900, 1000 to perform the functions described below. Additionally or alternatively, the computing device 900, 1000 may perform aspects of the functions described below using special-purpose hardware.

At 105, the method 100 may comprise: providing first information associated with the metro network, which include the topology of the metro network, service schedules of trains in the metro network, and information on fares for the trains. This corresponds to component 205 in the schematic representation 200 (of FIG. 2). In some instances, the first information may further include information on the types of trains operating in the metro network, and respective capacities of the trains.

At 110, the method 100 may comprise: providing second information associated with alternative modes of transportation to the metro network in the multi-modal transportation network, which include information on fares for the alternative modes of transportation and expected travel time for routes based on the alternative modes of transportation. This corresponds to component 210 in the schematic representation 200.

At 115, the method 100 may comprise: providing third information associated with the topology of a portion in the metro network associated with a service disruption. This corresponds to component 215 in the schematic representation 200. In some instances, the topology of the portion in the metro network may indicate at least one station affected by said service disruption.

At 120, the method 100 may comprise: providing fourth information associated with estimated diverted origin-destination-station (ODS) demand patterns for the service disruption. This corresponds to component 220 in the schematic representation 200.

At 125, the method 100 may comprise: providing fifth information associated with predicted irregular route choices of passengers in the multi-modal transportation network during service disruptions. The fifth information is generated by a “Passenger route choice” model 225 (see FIG. 2), and provided (as input) to the method 100.

At 130, the method 100 may comprise: predicting passenger flow patterns associated with the service disruption, through computationally simulating, based collectively on the first information, the second information, the third information, the fourth information and the fifth information. Additionally or optionally, predicting the passenger flow patterns 235 may include: outputting information on link flows along each metro line (in the metro network), and number of waiting passengers on the platforms arranged at the portion in the metro network associated with the service disruption.

It is to be appreciated that in an example, computationally simulating to predict the passenger flow patterns may be performed by an event-based metro system simulation model 230 (i.e. see FIG. 2). It is to be appreciated that the “Passenger route choice” model 225 and the event-based metro system simulation model 230 may together constitute a “Utility-based passenger behavior” model 240. The development of the “Utility-based passenger behavior” model 240 is set out in details below.

The event-based metro system simulation model 230 may be configured at least with information being: historical ODS demand patterns that are based on smart card data associated with travelling in the metro network (e.g. daily time-precise, entry-exit data registered through smart card payment transactions at gantries of stations in the metro network); and passenger load information of the trains during service disruptions, and during disruption-free operation of the metro network (i.e. normal operating conditions). The smart card data may include data associated with travelling in the metro network during service disruptions, and data associated with travelling in the metro network during disruption-free operation thereof.

It is to be appreciated that within the event-based metro system simulation model 230, given the metro network layout, train types and capacities, and service operating schedules, individual passengers of each ODS pairs are loaded onto the trains according to their route choices on a first come first served basis. For each ODS pair, a set of temporal expected travel times external to the metro network is compiled from various sources. Specifically, a complete set of historical ODS diversion data during previous service disruptions in the metro network is compiled. However, since historical ODS diversion data vis-à-vis the metro network lack information about passengers' alternative routes with transportation modes external to the metro network, such information is acquired from third-party navigation and route planning platforms (e.g. Google Maps, HKeMobility, or the like).

In relation to the “Passenger route choice” model 225, relative route utilities may be extracted from the event-based metro system simulation model 230 by comparing route features, such as route length and expected travel time experienced within the metro network relative to the expected travel time outside the metro network via other alternative modes of transportation. These features are used to calibrate the “Utility-based passenger behaviour” model 240 under the scenario of service disruption.

The disclosed method 100 is able to capture passenger diversion patterns both within and external to the metro network (such that the event-based metro system simulation model 230 may consider a comprehensive set of relative route utilities), without resorting to using an agent-based simulation model to generate the predicted passenger flow patterns 235 in a near real-time manner. The disclosed method 100 provides the ability to predict changes in ODS passenger demands in relation to service disruptions in the metro network and also encapsulates a calibrated passenger route choice behavior under service disruptions and the metro operator's service adjustments. It is to be appreciated that the method 100 may also be used for counterfactual studies on past cases, and for estimation studies on imaginary cases for predicting changes in ODS passenger demands vis-à-vis service disruptions in the metro network. Further, the event-based metro system simulation model 230 is configured to generate train and platform loadings in an efficient manner, thereby generating results that may facilitate development of mitigation strategies for emergency response management in a timely manner, when there is service disruption in the metro network. Specifically, passenger flow patterns are predicted by being realized in the form of train loading and platform loading (i.e. a number of passengers at respective locations at any point of the simulation time). That is, the passenger flow patterns are predicted in the granularity of origin-destination pairs, and all passengers are then aggregated as train loading by time.

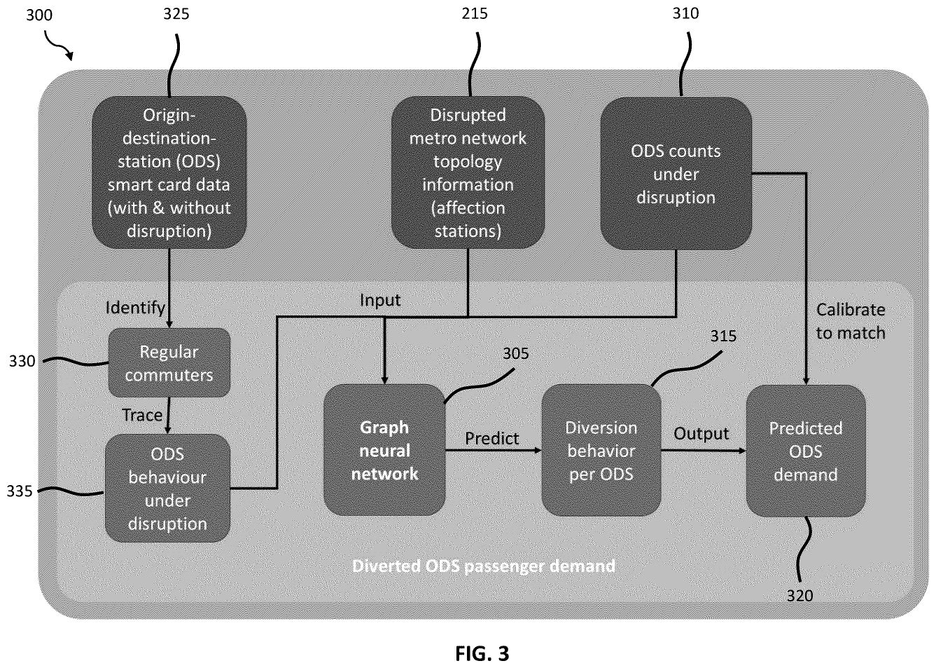

FIG. 3 is a schematic representation 300 of a statistical model for generating the fourth information vis-à-vis the estimated ODS demand patterns, in accordance with aspects of the present disclosure. Specifically, providing the fourth information (see FIG. 1) associated with the estimated diverted ODS demand patterns may include:
configuring a graph neural network (GNN) 305 (as a statistical model) to capture spatial and temporal information embedded in the metro network, wherein the GNN 305 is further configured with information on the topology of the metro network;
providing, to the GNN 305, the third information (i.e. the topology of the portion in the metro network associated with the service disruption);
providing, to the GNN 305, sixth information on origin-destination-station (ODS) pair passenger demand numbers associated with the service disruption, being ODS input counts under the service disruption (i.e. depicted as component 310 in FIG. 3); and
estimating, by the GNN 305 based on the third information and the sixth information, passenger diversion behaviour for each ODS pair (i.e. depicted as component 315 in FIG. 3), which collectively enable generation of the estimated diverted ODS demand patterns (i.e. depicted as component 320 in FIG. 3) as the fourth information. That is, the estimated passenger diversion behaviour for all ODS pairs together form the estimated diverted ODS demand patterns.

For completeness, this citation provides a study on state-of-the-art GNNs-Wu Z, Pan S, Chen F, et al.: “A Comprehensive Survey on Graph Neural Networks”, IEEE Transactions on Neural Networks and Learning Systems. 2021 January; 32 (1): 4-24. DOI: 10.1109/tnnls.2020.2978386. PMID: 32217482.

Additionally or alternatively, the information on the topology of the metro network may include information associated with costs of traveling between stations in the metro network and on links. It is to be appreciated that in transportation engineering, passengers may incur different various costs for traveling: e.g. monetary costs, time costs, discomfort costs and the like. So, the costs of traveling may be considered the general cost incurred by a passenger for traveling, which is viewed as a complex combination of the stated costs.

Additionally or alternatively, the GNN 305 may be pre-trained with historical ODS demand patterns (i.e. depicted as component 325 in FIG. 3) that are based on smart card data associated with travelling in the metro network, and in the historical ODS demand patterns, regular passengers (i.e. depicted as component 330 in FIG. 3) with habitual travel patterns may be identified as representative tracers to enable determination of passenger irregular route choices during service disruptions (i.e. depicted as component 335 in FIG. 3), based on the habitual travel patterns of said representative tracers.

It is to be appreciated that the smart card data associated with travelling in the metro network may include data associated with travelling in the metro network during service disruptions, and data associated with travelling in the metro network during disruption-free operation thereof.

Additionally or alternatively, the method 100 may further comprise: calibrating the number of ODS pair associated with the service disruption to match the estimated diverted ODS demand patterns. It is to be appreciated that the term “calibrating” in this context means the GNN 305 is suitably adjusted to predict the estimated diverted ODS demand patterns (i.e. depicted as component 320 in FIG. 3), under the service disruption, in order to thereby make it as close as possible (i.e. match) to the actual passenger ODS demand (i.e. depicted as component 310 in FIG. 3) under that service disruption, which may then imply the GNN 305 is performing well.

In some implementations, the operations of the method 100 may be programmed into, and stored as corresponding computer-readable code that is executable by the computing device 900, 1000 (or its components).

In accordance with aspects of the present disclosure, there is disclosed a computing device (e.g. the computing device 900, 1000, as depicted in FIGS. 9-10) for predicting passenger flow patterns during service disruptions in a metro network of a multi-modal transportation network, comprising: one or more memories having executable code; and one or more processors coupled to the one or more memories, and configured to execute the code to cause the device to:
1) provide first information associated with the metro network, which include the topology of the metro network, service schedules of trains in the metro network, and information on fares for the trains;
2) provide second information associated with alternative modes of transportation to the metro network in the multi-modal transportation network, which include information on fares for the alternative modes of transportation, and expected travel time for routes based on the alternative modes of transportation;
3) provide third information associated with the topology of a portion in the metro network associated with a service disruption;
4) provide fourth information associated with estimated diverted origin-destination-station (ODS) demand patterns for the service disruption;
5) provide fifth information associated with predicted irregular route choices of passengers in the multi-modal transportation network during service disruptions; and
6) predict passenger flow patterns associated with the service disruption, through computationally simulating, based collectively on the first information, the second information, the third information, the fourth information and the fifth information.

Further details on some aspects of the disclosed method 100 are set out in the description below.

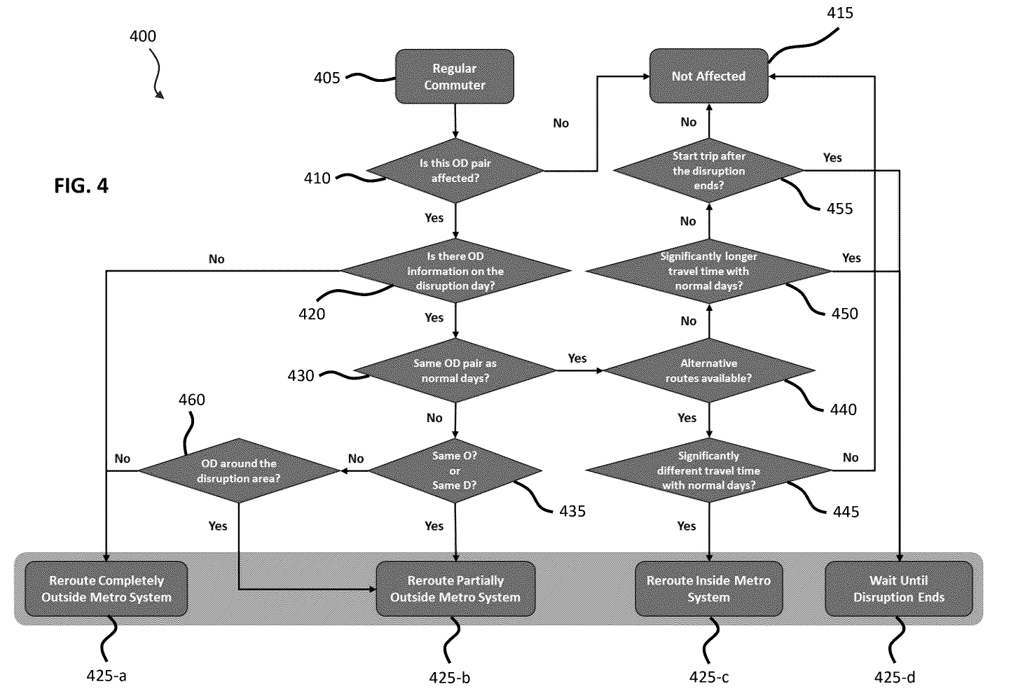

FIG. 4 is a flowchart depicting a method 400 (of an algorithm) for identifying representative passengers (i.e. regular commuters) with habitual travel patterns from smart card data associated with travelling in a metro network, in accordance with aspects of the present disclosure. To be clear, this is associated with the individual historical ODS travel patterns (i.e. depicted as component 325 in FIG. 3) based on smart card data associated with travelling in the metro network. Regular commuters may be defined as passengers who travelled between the same origin-destination (OD) pair during the disruption time period of the day on every weekday of the week, excluding the day of disruption. The following portions of pseudo-codes outline how the method 400 may flow accordingly vis-à-vis determinations made.

At step 405, a passenger indicated in the smart card data is initially presumed to be a regular commuter. At next step 410, it is determined if the OD pair for said passenger is affected (by the studied metro disruption), and the pseudo-code to be executed is:
If the OD pair for said passenger is affected (i.e. “Yes” route), flow progresses to step 420; else
If the OD pair for said passenger is not affected (i.e. “No” route), flow progresses to step 415.

At step 420, it is determined if there exists metro gantry entry and exit information on a day of service disruption, and the pseudo-code to be executed is:
If there exists metro gantry entry and exit information on a day of service disruption (i.e. “Yes” route), flow progresses to step 430; else.
If there are no metro gantry entry and exit information on a day of service disruption (i.e. “No” route), flow progresses to state 425-a.
   State 425-a pertains to “Reroute Completely Outside Metro network”, and means the passenger (identified at step 405) reroutes his/her travel completely outside the metro network (using other means of transportation), in contrast to re-routing partially the travel outside the metro network (by using both the metro network and other means of transportation for his/her original single trip). Alternatively, state 424-a may also be taken to mean that the passenger has forfeited/abandoned his/her travel. In this manner, the rerouting behavior of the passenger may be identified and categorized.

At step 430, it is determined if the affected OD pair (based on existence of the metro gantry entry and exit information on a day of service disruption) is the same as the OD pair on a disruption-free day, and the pseudo-code to be executed is:
If the affected OD pair (based on the metro gantry entry and exit information) is the same as the OD pair on the disruption-free day (i.e. “Yes” route), flow progresses to step 440; else.
If the affected OD pair (based on the metro gantry entry and exit information) is not the same as the OD pair on the disruption-free day (i.e. “No” route), flow progresses to step 435.

At step 435, it is determined if the origin or the destination is the same (by comparing the affected OD pair with the OD pair on the disruption-free day), and the pseudo-code to be executed is:
If the origin or the destination is the same (i.e. “Yes” route), flow progresses to state 425-b; else.
If the origin or the destination is not the same (i.e. “No” route), flow progresses to step 460.
   State 425-b pertains to “Reroute Partially Outside Metro network”, and means the passenger (identified at step 405) partially reroutes his/her travel outside the metro network/system (by using both the metro network and other means of transportation for his/her original single trip). More specifically, it implies the passenger travelled through only some segment(s) in the metro network/system, and his/her travel in the metro network/system is considered incomplete. For example, the passenger may originally intend to travel from metro station A to metro station C, via metro station B, but may have exited earlier instead at metro station B. It is then presumed the passenger may have completed his/her travel by other transportation modes in order to make the corresponding journey that spans from metro station B to metro station C. In this manner, the rerouting behavior of the passenger may be identified and categorized.

At step 460, it is determined if the affected OD pair is around the area where service disruption occurred, and the pseudo-code to be executed is:
If the affected OD pair is around the area where service disruption occurred (i.e. “Yes” route), flow progresses to state 425-b; else.
If the affected OD pair is not around the area where service disruption occurred (i.e. “No” route), flow progresses to state 425-a.

Now going to step 440 (based on the finding that the affected OD pair is the same as the OD pair on the disruption-free day), it is determined if alternative routes are available, and the pseudo-code to be executed is:
If alternative routes are available (i.e. “Yes” route), flow progresses to step 445; else
If alternative routes are not available (i.e. “No” route), flow progresses to step 450.

At step 445, it is determined if the available alternative routes have significantly different travel time versus corresponding routes on the metro network taken on disruption-free days, and the pseudo-code to be executed is:
If the travel time is significantly different (i.e. “Yes” route), flow progresses to state 425-c; else.
If the travel time is not affected (i.e. “No” route), flow progresses to step 415.
   State 425-c pertains to “Reroute Inside Metro network”, and means the passenger (identified at step 405) chooses a different (new) route due to the service disruption to continue his/her travel, but the chosen new route is still completely within the metro network/system.

At step 450, it is determined if it takes significantly longer travel time compared to travelling on the metro network on disruption-free days, and the pseudo-code to be executed is:
If the travel time is significantly longer (i.e. “Yes” route), flow progresses to state 425-d; else
If the travel time is not significantly longer (i.e. “No” route), flow progresses to step 455.
   State 425-d pertains to “Wait Until Disruption Ends”, and means the passenger (identified at step 405) chooses to pause his/her travel until the disruption ends, and thereafter, the passenger takes the original route as intended to complete his/her travel.

At step 455, it is determined if the passenger starts a trip after the service disruption ends, and the pseudo-code to be executed is:
If the passenger starts a trip after the service disruption ends (i.e. “Yes” route), flow progresses to state 425-d; else.
If the passenger does not start a trip after the service disruption ends (i.e. “No” route), flow progresses to step 415.

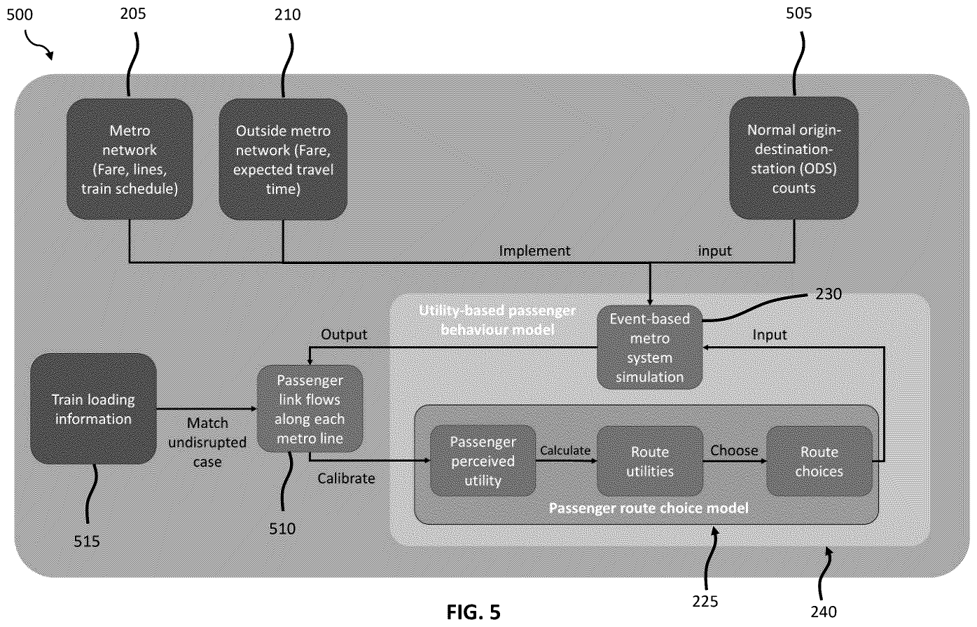

FIG. 5 is a schematic representation 500 of an implementation of the event-based metro system simulation model 230 used in the method 100 of FIG. 1, in accordance with aspects of the present disclosure. To develop the event-based metro system simulation model 230, the following information (represented as components in FIG. 5) are provided to said model 230:
Information associated with the metro network, which include the topology of the metro network, service schedules of trains in the metro network, and information on fares for the trains. This is represented as component 205 in FIG. 5.
Information associated with alternative modes of transportation to the metro network in the multi-modal transportation network, which include information on fares for the alternative modes of transportation, and expected travel time for routes based on the alternative modes of transportation. This is represented as component 210 in FIG. 5.
Information on a normal ODS counts, which, in the context of disruption-free operation (i.e. as defined by “normal”), sets out the number of passengers traveling from one origin station to a destination station (a ODS pair). For example, there may be 10 passengers traveling between metro station A and metro station B, or there may be 20 passengers traveling between metro station C and metro station D. The ODS counts is thus 10 and 20 respectively in the said two examples. This is represented as component 505 in FIG. 5.
Information associated with predicted irregular route choices of passengers in the multi-modal transportation network during service disruptions. This information is generated by the “Passenger route choice” model 225.

The above information is loaded into the event-based metro system simulation model 230 to develop/implement said model 230. The event-based metro system simulation model 230 outputs information pertaining to passenger link flows along each metro line (represented as component 510 in FIG. 5). Next, passenger load information (represented as component 515 in FIG. 5) of the trains during disruption-free operation of the metro network are used to match undisrupted cases with the information pertaining passenger link flows along each metro line to obtain a set of results, which are then used to calibrate the “Passenger route choice” model 225. In this way, the passenger load information may be used to calibrate the “Passenger route choice” model 225 under disruption through the event-based metro system simulation model 230. It is to be appreciated the “Passenger route choice” model 225 refers to a model that is configured to predict passenger route choices behaviors specifically for normal cases without disruption, and therefore the passenger load information of the trains is used to “match undisrupted case” with the information of passenger link flows along each metro line (i.e. component 510 in FIG. 5) output by the event-based metro system simulation model 230.

FIG. 6 is a block diagram of a device 605 for predicting passenger flow patterns during service disruptions in a metro network of a multi-modal transportation network, in accordance with aspects of the present disclosure. The device 605 may be an example of aspects of a computing device 900, 1000 of FIGS. 9-10, and may be configured to perform the method 100 of FIG. 1. The device 605 may include a receiver 610, a compute manager 615, and a transmitter 620. The compute manager 615 may be implemented, at least in part, by one or both of a modem and a processor. Each of these components may be in communication with one another (e.g. via one or more buses).

The receiver 610 may receive information such as packets, user data, or control information associated with various information channels (e.g. control channels, data channels, or the like). Information may be passed on to other components of the device 605. The receiver 610 may be an example of aspects of a radio receiver, or an Ethernet adaptor. In some examples, the receiver 610 may utilize a single antenna or a set of antennas (e.g. for MIMO communications).

The compute manager 615 may be configured to perform the following:
1) providing first information associated with the metro network, which include the topology of the metro network, service schedules of trains in the metro network, and information on fares for the trains;
2) providing second information associated with alternative modes of transportation to the metro network in the multi-modal transportation network, which include information on fares for the alternative modes of transportation, and expected travel time for routes based on the alternative modes of transportation;
3) providing third information associated with the topology of a portion in the metro network associated with a service disruption;
4) providing fourth information associated with estimated diverted origin-destination-station (ODS) demand patterns for the service disruption;
5) providing fifth information associated with predicted irregular route choices of passengers in the multi-modal transportation network during service disruptions; and
6) predicting passenger flow patterns associated with the service disruption, through computationally simulating, based collectively on the first information, the second information, the third information, the fourth information and the fifth information.

The transmitter 620 may transmit signals generated by other components of the device 605. For example, the transmitter 620 may be an example of aspects of a radio transmitter, or an Ethernet adaptor. In some examples, the transmitter 620 may utilize a single antenna or a set of antennas (e.g. for MIMO communications). In some examples, the transmitter 620 may be collocated with the receiver 1210 in a transceiver component.

FIG. 7 is a block diagram of a device 705 for predicting passenger flow patterns during service disruptions in a metro network of a multi-modal transportation network, in accordance with aspects of the present disclosure. The device 705 may be an example of aspects of a device 605, or a computing device 900, 1000 of FIGS. 9-10, and may be configured to perform the method 100 of FIG. 1. The device 705 may include a receiver 710, a compute manager 715, and a transmitter 720. The compute manager 715 may be implemented, at least in part, by one or both of a modem and a processor. Each of these components may be in communication with one another (e.g. via one or more buses).

The receiver 710 may receive information such as packets, user data, or control information associated with various information channels (e.g. control channels, data channels, or the like). Information may be passed on to other components of the device 705. The receiver 710 may be an example of aspects of a radio receiver, or an Ethernet adaptor. The receiver 710 may utilize a single antenna or a set of antennas (e.g. for MIMO communications).

The compute manager 715 may include a first (1^{st}) provide component 715-1, a second (2^{nd}) provide component 715-2, a third (3^{rd}) provide component 715-3, a fourth (4^{th}) provide component 715-4, a fifth (5^{th}) provide component 715-5, and a simulation component 725.

In some examples, it is possible that the 1^{st} provide component 715-1, the 2^{nd} provide component 715-2, the 3^{rd} provide component 715-3, the 4^{th} provide component 715-4, and the 5^{th} provide component 715-5 may alternatively be realised as a single provide component (not shown) configured to provide the collective functionalities of all said provide components 715-1, 715-2, 715-3, 715-4, 715-5.

The 1^{st} provide component 715-1 may provide first information associated with the metro network, which include the topology of the metro network, service schedules of trains in the metro network, and information on fares for the trains.

The 2^{nd} provide component 715-2 may provide second information associated with alternative modes of transportation to the metro network in the multi-modal transportation network, which include information on fares for the alternative modes of transportation, and expected travel time for routes based on the alternative modes of transportation.

The 3^{rd} provide component 715-3 may provide third information associated with the topology of a portion in the metro network associated with a service disruption.

The 4^{th} provide component 715-4 may provide fourth information associated with estimated diverted origin-destination-station (ODS) demand patterns for the service disruption.

The 5^{th} provide component 715-5 may provide fifth information associated with predicted irregular route choices of passengers in the multi-modal transportation network during service disruptions.

The simulation component 725 may predict passenger flow patterns associated with the service disruption, through computationally simulating, based collectively on the first information, the second information, the third information, the fourth information and the fifth information.

The transmitter 720 may transmit signals generated by other components of the device 705. For example, the transmitter 720 may be an example of aspects of a radio transmitter, or an Ethernet adaptor. The transmitter 720 may utilize a single antenna or a set of antennas (e.g. for MIMO communications). In some examples, the transmitter 720 may be collocated with the receiver 710 in a transceiver component.

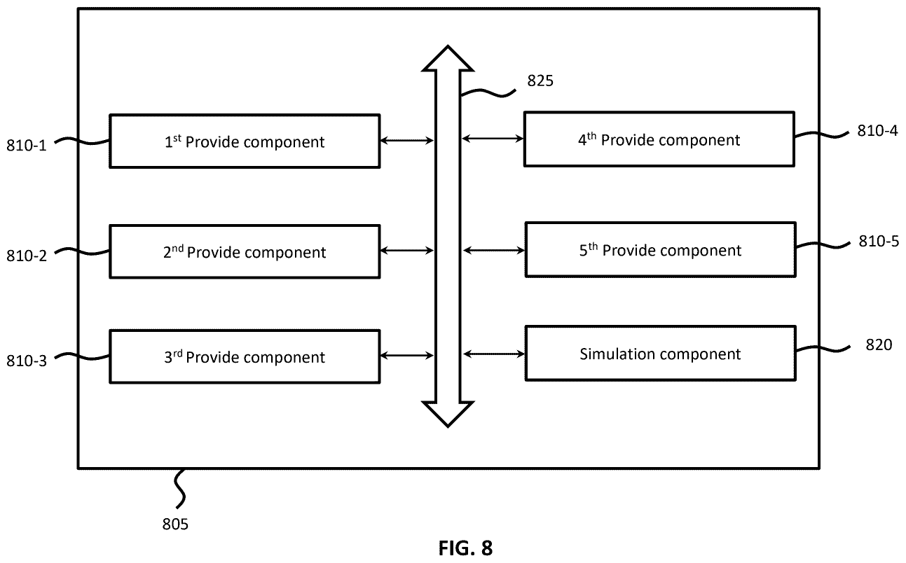

FIG. 8 is a block diagram of a communications manager 805 for predicting passenger flow patterns during service disruptions in a metro network of a multi-modal transportation network, in accordance with aspects of the present disclosure. The communications manager 805 may be an example of aspects of a compute manager 615 (in FIG. 6), or a compute manager 715 (in FIG. 7) described herein. The communications manager 805 may include a first (1^{st}) provide component 810-1, a second (2^{nd}) provide component 810-2, a third (3^{rd}) provide component 810-3, a fourth (4^{th}) provide component 810-4, a fifth (5^{th}) provide component 810-5, and a simulation component 820. Each of these components may communicate 825, directly or indirectly, with one another (e.g. via one or more buses).

The 1^{st} provide component 810-1 may provide first information associated with the metro network, which include the topology of the metro network, service schedules of trains in the metro network, and information on fares for the trains.

The 2^{nd} provide component 810-2 may provide second information associated with alternative modes of transportation to the metro network in the multi-modal transportation network, which include information on fares for the alternative modes of transportation, and expected travel time for routes based on the alternative modes of transportation.

The 3^{rd} provide component 810-3 may provide third information associated with the topology of a portion in the metro network associated with a service disruption.

The 4^{th} provide component 810-4 may provide fourth information associated with estimated diverted origin-destination-station (ODS) demand patterns for the service disruption.

The 5^{th} provide component 810-5 may provide fifth information associated with predicted irregular route choices of passengers in the multi-modal transportation network during service disruptions.

The simulation component 820 may predict passenger flow patterns associated with the service disruption, through computationally simulating, based collectively on the first information, the second information, the third information, the fourth information and the fifth information.

In some examples, it is possible that the 1^{st} provide component 810-1, the 2^{nd} provide component 810-2, the 3^{rd} provide component 810-3, the 4^{th} provide component 810-4, and the 5^{th} provide component 810-5 may be implemented as a single provide component (not shown) configured to collectively perform all the functions of said provide components 810-1, 810-2, 810-3, 810-4, 810-5.

FIG. 9 is a schematic diagram of an exemplary (first) computing device 900 for executing and performing the method 100 of FIG. 1, in accordance with aspects of the present disclosure.

The computing device 900 may comprise a keypad 902, a touch-screen 904, a microphone 906, a speaker 908 and an antenna 910. The computing device 900 may be operated by a user to perform a variety of different functions/tasks, for example, making a telephone call, sending an SMS message, browsing the Internet, sending emails, providing satellite navigation, or the like.

The computing device 900 may comprise hardware to perform communication functions (e.g. telephony, or data communication), together with an application processor and corresponding supporting hardware to enable the computing device 900 to establish other functions, for example, messaging, Internet browsing, email functions or the like. The communication hardware may include a radio frequency (RF) processor 912, which provides an RF signal to the antenna 910 for the transmission of data signals, and the receipt therefrom. A baseband processor 914 may be provided, which provides signals to, and receives signals from the RF processor 912. The baseband processor 914 may also interact with a subscriber identity module (SIM) 916, as known in the art. The communication subsystem enables the computing device 900 to communicate via a number of different communication protocols including 3G, 4G, 5G, New Radio (NR), GSM, WiFi, Bluetooth™ and/or CDMA. The communication subsystem of the computing device 900 is beyond the scope of the present disclosure.

The keypad 902 and the touch-screen 904 are controlled by an application processor 918. A power and audio controller 920 is provided to supply power from a battery 922 to the communication subsystem, the application processor 918, and the other hardware. The power and audio controller 920 may also control input from the microphone 906, and audio output via the speaker 908. There may also be provided a global positioning system (GPS) antenna and associated receiver element 924, which is controlled by the application processor 918 and is capable of receiving a GPS signal for use with a satellite navigation functionality of the computing device 900.

Various different types of memory may be provided in the computing device 900 to supplement operations of the application processor 918. The computing device 900 may include Random Access Memory (RAM) 926 coupled to the application processor 918 into which data and program code may be written and read from. Executable code stored in RAM 926 may be executed by the application processor 918 from RAM 926. RAM 926 represents a form of volatile memory of the computing device 900.

The computing device 900 may further be provided with a non-volatile (long-term) storage 928 coupled to the application processor 918. The storage 928 may logically be divided into three partitions: an operating system (OS) partition 930, a system partition 932, and a user partition 934. The storage 928 may represent a non-volatile memory of the computing device 900.

In an example, the OS partition 930 may include firmware of the computing device 900, which includes an operating system. Other computer programs may also be stored in the storage 928, such as application programs (also referred to as apps), and the like. Particularly, application programs considered critical to functioning of the computing device 900, for example, in the case of a smartphone, communications applications and the like, are typically stored in system partition 932. The application programs stored on the system partition 932 typically may be programmed in the computing device 900 in its default factory setting.

Application programs subsequently added and installed on the computing device 900 by the user may typically be stored in the user partition 934.

The various functional components illustrated in FIG. 9 may alternatively be collocated into a single component. For example, the storage 928 may comprise NAND flash, NOR flash, a hard disk drive or a combination of these.

FIG. 10 is a schematic diagram of an exemplary (second) computing device 1000 that may be utilized for executing and performing the method 100 of FIG. 1, in accordance with aspects of the present disclosure. The following description of the computing device 1000 is provided by way of example only and is not intended to be limiting.

As depicted in FIG. 10, the example computing device 1000 may include a processor 1004 for executing software routines/programs. While only a single processor is shown for brevity, the computing device 1000 may also be configured as a multi-processor system (i.e. includes multiple processors). The processor 1004 is coupled to a communication infrastructure 1006 for communication with other components of the computing device 1000.

The communication infrastructure 1006 may include, for example, a communications bus, a crossbar network, or a network.

The computing device 1000 further includes a main memory 1008, such as a random-access memory (RAM), and a secondary memory 1010. The secondary memory 1010 may include, for example, a hard disk drive 1012 and/or a removable storage drive 1014, which may include a floppy disk drive, a magnetic tape drive, an optical disk drive, or the like. The removable storage drive 1014 reads from and/or writes to a removable storage unit 1018, as known in the art. The removable storage unit 1018 may include a floppy disk, magnetic tape, optical disk, universal serial bus (USB) flash disk, or the like, which is read by and/or written to by removable storage drive 1014. As may be appreciated by skilled persons in the art, the removable storage unit 1018 may further include a computer readable storage medium having stored therein computer executable program code instructions and/or data.

In other aspects, the secondary memory 1010 may additionally or alternatively include other similar means for allowing computer programs or other instructions to be loaded into the computing device 1000 for execution. Such means may include, for example, a removable storage unit 1022 and an associated interface 1020. Examples of a removable storage unit 1022 and interface 1020 may include a USB flash drive and a USB interface, a program cartridge and cartridge interface (e.g. such as that found in video game console devices), a removable memory chip (e.g. an EPROM or PROM) and associated socket, and other exemplary removable storage units 1022 and interfaces 1020, which may enable software programs and/or data to be transferred between the removable storage unit 1022 and the computing device 1000.

The computing device 1000 also includes at least one communication interface 1024. The communication interface 1024 allows software programs and data to be transferred between computing device 1000 and external devices, via communication path 1026. In various aspects, the communication interface 1024 permits data to be transferred between the computing device 1000 and a data communication network, such as a public data or private data communication network. The communication interface 1024 may be used to exchange data between different computing devices 1000 that may together form part of an interconnected computer network. Examples of a communication interface 1024 may include a modem, a network interface (e.g. an Ethernet card), a communication port, an antenna with associated circuitry or the like. The communication interface 1024 may be configured as wired or wireless. Software and data transferred via the communication interface 1024 are in the form of signals, which can be electronic, electromagnetic, optical or other signals capable of being received by communication interface 1024. These signals are provided to the communication interface via the communication path 1026.

The computing device 1000 further may include a display interface 1002 configured to perform operations for rendering images to an associated display 1030, and an audio interface 1032 for performing operations for playing audio content via associated speaker(s) 1034.

As used herein, the term “computer program product” may refer, in part, to the removable storage unit 1018, the removable storage unit 1022, a hard disk installed in the hard disk drive 1012, or a carrier wave carrying software over the communication path 1026 (e.g. via a wireless link, or a cable) to the communication interface 1024. Computer readable storage media refers to any non-transitory tangible storage medium that provides recorded instructions and/or data to the computing device 1000 for execution and/or processing. Examples of such storage media include floppy disks, USB disk, magnetic tape, CD-ROM, DVD, Blu-ray™ Disc, a hard disk drive, a ROM or integrated circuit, USB memory, a magneto-optical disk, or a computer readable card such as a PCMCIA card or the like, whether or not such devices are internal or external of the computing device 1000. Examples of transitory or non-tangible computer readable transmission media that may also participate in the provision of software, application programs, instructions and/or data to the computing device 1000 include radio or infra-red transmission channels as well as a network connection to another computer or networked device, and the Internet or Intranets including e-mail transmissions and information recorded on websites and the like.

The computer programs (also termed computer program code/instruction) are stored in the main memory 1008 and/or the secondary memory 1010. Computer programs may also be received via the communication interface 1024. Such computer programs, when executed, enable the computing device 1000 to perform one or more aspects of the present disclosure afore discussed. In various aspects of the present disclosure, the computer programs, which when executed, enable the processor 1004 to perform aspect(s) of the present disclosure. Accordingly, such computer programs may represent (logic) controllers of the computing device 1000.

Software may be stored in a computer program product and loaded into the computing device 1000, using the removable storage drive 1014, the hard disk drive 1012, or the interface 1020. Alternatively, the computer program product may be downloaded directly onto the computing device 1000, via the communication path 1026. The software, when executed by the processor 1004, causes the computing device 1000 to perform aspects of the present disclosure.

It is to be understood that the computing device 1000 in FIG. 10 is presented merely by way of example. Hence, in some aspects, one or more features of the computing device 1000 may be omitted. Also, in other aspects, one or more features of the computing device 1000 may be combined together, or collocated. Additionally, in some aspects, one or more features of the computing device 1000 may be divided into one or more component parts.

It is to be appreciated that the elements illustrated in FIG. 10 may further function to provide means for performing the various functions of the disclosed method 100 in FIG. 1, as described in accordance with aspects of the present disclosure. Also, the term “computing device” 900, 1000 may include or may refer to a mobile device, a wireless device, a remote device, a handheld device, a smartphone, a tablet computer, a laptop computer, a computer server, a computer terminal, a blade server, among other examples. The computing device 900, 1000 described herein may be able to communicate with various types of devices, such as other computing devices 900, 1000 that may sometimes act as relays, or work together under configuration to function as a computer cluster for performing high-performance computing.

All of the methods described herein describe possible implementations, and that the operations and the steps may be rearranged or otherwise modified and that other implementations are possible. Further, aspects from two or more of the methods, if applicable, may be combined.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed with a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (for example, a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that may be accessed by a general-purpose or special purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (such as, A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on”.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples”. The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein, but to be accorded the broadest scope consistent with the principles and novel features disclosed herein.

### EXAMPLES

The following examples are disclosed, in accordance with aspects of the present disclosure.

Example 1: A computer-implemented method for predicting passenger flow patterns during service disruptions in a metro network of a multi-modal transportation network, the method comprises: providing first information associated with the metro network, which include the topology of the metro network, service schedules of trains in the metro network, and information on fares for the trains; providing second information associated with alternative modes of transportation to the metro network in the multi-modal transportation network, which include information on fares for the alternative modes of transportation, and expected travel time for routes based on the alternative modes of transportation; providing third information associated with the topology of a portion in the metro network associated with a service disruption; providing fourth information associated with estimated diverted origin-destination-station (ODS) demand patterns for the service disruption; providing fifth information associated with predicted irregular route choices of passengers in the multi-modal transportation network during service disruptions; and predicting passenger flow patterns associated with the service disruption, through computationally simulating, based collectively on the first information, the second information, the third information, the fourth information and the fifth information.

Example 2: The method of example 1, wherein predicting the passenger flow patterns includes: outputting information on link flows along each metro line, and number of waiting passengers on the platforms arranged at the portion in the metro network associated with the service disruption.

Example 3: The method of any of examples 1-2, wherein the topology of the portion in the metro network indicates at least one station affected by said service disruption.

Example 4: The method of any of examples 1-3, wherein providing the fourth information associated with the estimated diverted ODS demand patterns includes: configuring a graph neural network (GNN) to capture spatial and temporal information embedded in the metro network, wherein the GNN is further configured with information on the topology of the metro network; providing, to the GNN, the third information; providing, to the GNN, sixth information on origin-destination-station (ODS) pair passenger demand numbers associated with the service disruption; and estimating, by the GNN based on the third information and the sixth information, passenger diversion behaviour for each ODS pair, which collectively enable generation of the estimated diverted ODS demand patterns as the fourth information.

Example 5: The method of example 4, further comprising calibrating the number of ODS pair associated with the service disruption to match the estimated diverted ODS demand patterns.

Example 6: The method of example 4, wherein the information on the topology of the metro network includes information associated with costs of traveling between stations in the metro network and on links.

Example 7: The method of example 4, wherein the GNN is pre-trained with historical ODS demand patterns that are based on smart card data associated with travelling in the metro network, and wherein in the historical ODS demand patterns, regular passengers with habitual travel patterns are identified as representative tracers to enable determination of passenger irregular route choices during service disruptions, based on the habitual travel patterns of said representative tracers.

Example 8: The method of example 7, wherein the smart card data associated with travelling in the metro network include data associated with travelling in the metro network during service disruptions, and data associated with travelling in the metro network during disruption-free operation thereof.

Example 9: The method of any of examples 1-8, wherein the first information further include information on the types of trains operating in the metro network, and respective capacities of the trains.

Example 10: The method of any of examples 1-9, wherein computationally simulating to predict the passenger flow patterns is performed by an event-based metro system simulation model.

Example 11: The method of any of examples 1-10, wherein the event-based metro system simulation model is configured at least with information being: historical ODS demand patterns that are based on smart card data associated with travelling in the metro network, wherein the smart card data include data associated with travelling in the metro network during service disruptions, and data associated with travelling in the metro network during disruption-free operation thereof; and passenger load information of the trains during service disruptions, and during disruption-free operation of the metro network.

Example 12: A computing device for predicting passenger flow patterns during service disruptions in a metro network of a multi-modal transportation network, comprising: one or more memories having executable code; and one or more processors coupled to the one or more memories, and configured to execute the code to cause the device to: provide first information associated with the metro network, which include the topology of the metro network, service schedules of trains in the metro network, and information on fares for the trains; provide second information associated with alternative modes of transportation to the metro network in the multi-modal transportation network, which include information on fares for the alternative modes of transportation, and expected travel time for routes based on the alternative modes of transportation; provide third information associated with the topology of a portion in the metro network associated with a service disruption; provide fourth information associated with estimated diverted origin-destination-station (ODS) demand patterns for the service disruption; provide fifth information associated with predicted irregular route choices of passengers in the multi-modal transportation network during service disruptions; and predict passenger flow patterns associated with the service disruption, through computationally simulating, based collectively on the first information, the second information, the third information, the fourth information and the fifth information.

Example 13: A computing device for predicting passenger flow patterns during service disruptions in a metro network of a multi-modal transportation network, comprising: means for providing first information associated with the metro network, which include the topology of the metro network, service schedules of trains in the metro network, and information on fares for the trains; means for providing second information associated with alternative modes of transportation to the metro network in the multi-modal transportation network, which include information on fares for the alternative modes of transportation, and expected travel time for routes based on the alternative modes of transportation; means for providing third information associated with the topology of a portion in the metro network associated with a service disruption; means for providing fourth information associated with estimated diverted origin-destination-station (ODS) demand patterns for the service disruption; means for providing fifth information associated with predicted irregular route choices of passengers in the multi-modal transportation network during service disruptions; and means for predicting passenger flow patterns associated with the service disruption, through computationally simulating, based collectively on the first information, the second information, the third information, the fourth information and the fifth information.

Example 14: A non-transitory computer-readable medium comprising executable code, which when executed by a processor of a computing device, cause the device to perform the method of any of examples 1-11.

1. A computer-implemented method for predicting passenger flow patterns during service disruptions in a metro network of a multi-modal transportation network, the method comprises:
providing first information associated with the metro network, which include the topology of the metro network, service schedules of trains in the metro network, and information on fares for the trains;
providing second information associated with alternative modes of transportation to the metro network in the multi-modal transportation network, which include information on fares for the alternative modes of transportation, and expected travel time for routes based on the alternative modes of transportation;
providing third information associated with the topology of a portion in the metro network associated with a service disruption;
providing fourth information associated with estimated diverted origin-destination-station (ODS) demand patterns for the service disruption;
providing fifth information associated with predicted irregular route choices of passengers in the multi-modal transportation network during service disruptions; and
predicting passenger flow patterns associated with the service disruption, through computationally simulating, based collectively on the first information, the second information, the third information, the fourth information and the fifth information.

2. The method of claim 1, wherein predicting the passenger flow patterns includes:
outputting information on link flows along each metro line, and number of waiting passengers on the platforms arranged at the portion in the metro network associated with the service disruption.

3. The method of claim 1, wherein the topology of the portion in the metro network indicates at least one station affected by said service disruption.

4. The method of claim 1, wherein providing the fourth information associated with the estimated diverted ODS demand patterns includes:
configuring a graph neural network (GNN) to capture spatial and temporal information embedded in the metro network, wherein the GNN is further configured with information on the topology of the metro network;
providing, to the GNN, the third information;
providing, to the GNN, sixth information on origin-destination-station (ODS) pair passenger demand numbers associated with the service disruption; and
estimating, by the GNN based on the third information and the sixth information, passenger diversion behaviour for each ODS pair, which collectively enable generation of the estimated diverted ODS demand patterns as the fourth information.

5. The method of claim 4, further comprising calibrating the number of ODS pair associated with the service disruption to match the estimated diverted ODS demand patterns.

6. The method of claim 4, wherein the information on the topology of the metro network includes information associated with costs of traveling between stations in the metro network and on links.

7. The method of claim 4, wherein the GNN is pre-trained with historical ODS demand patterns that are based on smart card data associated with travelling in the metro network, and wherein in the historical ODS demand patterns, regular passengers with habitual travel patterns are identified as representative tracers to enable determination of passenger irregular route choices during service disruptions, based on the habitual travel patterns of said representative tracers.

8. The method of claim 7, wherein the smart card data associated with travelling in the metro network include data associated with travelling in the metro network during service disruptions, and data associated with travelling in the metro network during disruption-free operation thereof.

9. The method of claim 1, wherein the first information further include information on the types of trains operating in the metro network, and respective capacities of the trains.

10. The method of claim 1, wherein computationally simulating to predict the passenger flow patterns is performed by an event-based metro system simulation model.

11. The method of claim 1, wherein the event-based metro system simulation model is configured at least with information being:
historical ODS demand patterns that are based on smart card data associated with travelling in the metro network, wherein the smart card data include data associated with travelling in the metro network during service disruptions, and data associated with travelling in the metro network during disruption-free operation thereof; and
passenger load information of the trains during service disruptions, and during disruption-free operation of the metro network.

12. A computing device for predicting passenger flow patterns during service disruptions in a metro network of a multi-modal transportation network, comprising:
one or more memories having executable code; and
one or more processors coupled to the one or more memories, and configured to execute the code to cause the device to:
provide first information associated with the metro network, which include the topology of the metro network, service schedules of trains in the metro network, and information on fares for the trains;
provide second information associated with alternative modes of transportation to the metro network in the multi-modal transportation network, which include information on fares for the alternative modes of transportation, and expected travel time for routes based on the alternative modes of transportation;
provide third information associated with the topology of a portion in the metro network associated with a service disruption;
provide fourth information associated with estimated diverted origin-destination-station (ODS) demand patterns for the service disruption;
provide fifth information associated with predicted irregular route choices of passengers in the multi-modal transportation network during service disruptions; and
predict passenger flow patterns associated with the service disruption, through computationally simulating, based collectively on the first information, the second information, the third information, the fourth information and the fifth information.

13. A non-transitory computer-readable medium comprising executable code, which when executed by a processor of a computing device, cause the device to perform the method of claim 1.
